(19) United States
(12) Patent Application Publication
(10) Pub. No.: US 2012/0078545 A1
(43) Pub. Date: Mar. 29, 2012

(54) MULTI-LINE POWER MEASURING SYSTEM WHICH IMPROVES EFFICIENCY AND SIMPLICITY

(75) Inventors: Wonbok Hong, Gyeonggi-do (KR); Minsu Kim, Gyeonggi-do (KR); Yongju Kim, Seoul (KR); Junghun Yun, Gyeonggi-do (KR); Googchun Cho, Gyeonggi-do (KR); Youngbok Byun, Gyeonggi-do (KR); Jongju Lee, Gyeongsangnam-do (KR)

(73) Assignee: ROOTECH, INC., Suwon, Gyeonggi-do (KR)

(21) Appl. No.: 13/375,535

(22) PCT Filed: Jul. 6, 2010
(86) PCT No.: PCT/KR10/04385

§ 371 Date: Dec. 1, 2011

(30) Foreign Application Priority Data
Aug. 7, 2009 (KR) 10-2009-0072883

(51) Int. Cl. G01R 21/06; G06F 19/00

(52) U.S. Cl. 702/60

(57) ABSTRACT

Provided is a power measuring system for measuring power of a main circuit of incoming feeder and a branch circuit in a distribution panel, cabinet panel, or motor control center. The power measuring system includes a voltage sensing unit for sensing analog voltage of the main circuit and generating main voltage data by converting the sensed analog voltage to digital form, a current sensing unit for generating main current data of the main circuit or sub current data of the branch circuit, and a current data communication unit or voltage data communication unit for transmitting the sensed data or power-related data generated using the sensed data, wherein main circuit power data or branch circuit power data is calculated and displayed or transmitted.

### BACKGROUND OF THE INVENTION

The present invention relates to a power measuring device which receives a voltage signal and a current signal from a distribution panel, a cabinet panel, or a motor control center to measure power, and more particularly, to a system configured with measuring devices for efficient and simple wiring to measure power and power quality of a main circuit and all branch circuits from incoming feeder.

Generally, for measuring power, voltage and current on a power load are sensed and inputted to a power measuring device. Then, the power measuring device converts the sensed values in an analog-to-digital converter (ADC) after preprocessing them, and calculates the average power by calculating a per-cycle average through multiply and accumulate operations. For sensing voltage and current, a potential transformer (PT) and a current transformer (CT) are used to convert actual voltage and current into analog voltage and current signals, and any of variously implemented PTs and CTs capable of sensing voltage and current may be used, for which further description will not be provided.

FIG. 1 illustrates a configuration of a typical distribution panel or cabinet panel. A main circuit of incoming feeder introduced to a distribution panel and a cabinet panel passes through a molded case circuit breaker (MCCB) to be divided into multiple branch circuits, and passes through each MCCB of the branch circuits to be supplied to a load for each branch circuit.

FIG. 2 illustrates an exemplary configuration for measurement on a distribution panel or cabinet panel. A measuring unit (MU) 10 installed on a main circuit and a branch circuit measures voltage and current to calculate power and transmit the calculated power, and a display unit (DU) 20 displays the calculated power received from the MU 10 in analog or digital format.

FIG. 3 illustrates a configuration of a general MU. The MU is based on a processor such as a microcontroller or digital signal processor (DSP), and includes a voltage sensing unit 11, a current sensing unit 12, a power calculation unit 13, a communication unit 14, and an MU control unit 15. The voltage sensing unit 11 converts an analog voltage signal measured by a PT into voltage data using an ADC, and the current sensing unit 12 converts an analog current signal measured by a CT into current data using an ADC.

The power calculation unit 13 calculates power data using the thus generated voltage data and current data, and transmits the calculated power to the DU 20 so that the calculated power is displayed. The MU control unit 15 controls the voltage sensing unit 11, the current sensing unit 12, the power calculation unit 13, and the communication unit 14 included in the MU 10.

As illustrated in FIG. 4, the MU 10 is classified into a terminal-type MU having a terminal block with a bolt-tightening structure and a through-type MU without a bolt-tightening structure. While it is easy to connect the terminal-type MU to an MCCB by virtue of the terminal block, the terminal-type MU occupies a large area. Therefore, there is a limitation in applying the terminal-type MU to a branch circuit of a cabinet panel having limited space. While the through-type MU is spatially advantageous because a wiring path runs through it, its configuration is made very complicated because a voltage measuring terminal must additionally be provided for combining wires in order to measure voltage and power. In a through-type MU, current can be sensed using a thru-hole because a CT does not need to be directly wired with a power line; however, a wiring with the power line is still needed for voltage sensing using a PT.

The MU 10 may be disposed on a main circuit of incoming feeder and each branch circuit. For measurement on the incoming feeder only, the MU 10 is installed only on the incoming feeder, and if measurement on each branch circuit is also required, the MU 10 is also installed on each branch circuit.

FIG. 5 illustrates a configuration of a general DU. A DU 20 includes a display unit 21, a display communication unit 22, and a display control unit 23. The display communication unit 22 displays power data received from the MU 10 on the display unit 21 included in the DU 20, or transmits the power data to a host system in response to a request from the host system. The display control unit 23 controls operations of the display unit 21 and the display communication unit 22 included in the DU 20.

According to the configuration described above referring to FIGS. 2 to 5, each MU 10 independently senses voltage and current to perform an arithmetic operation. Thus, each MU 10 may independently operate without interference from another MU 10. The power data and power quality data independently calculated may be transmitted to the DU 20 by connecting multiple MUs 10 to a single network and using serial communication such as RS-485 communication, which is capable of multi-drop. However, voltages and currents should be sensed by each MU 10, and accordingly, many wires should be made. Thus, installation and wiring are not simple, and a large area is occupied.

FIG. 6 illustrates another exemplary configuration for measurement on a distribution panel or a cabinet panel. An MU 10 installed on each branch circuit in FIG. 2 is substituted with a CT 40, and an MU 10 of incoming feeder is substituted with a total measuring unit (TMU) 30. The TMU 30 will be described in detail later with reference to FIG. 7.

Since analog signals of currents flowing in each branch circuit should be transmitted to the TMU 30, separated signal lines for transmitting the analog current signals should be connected to each CT 40 installed on each branch circuit.

FIG. 7 illustrates a configuration of the TMU 30. The TMU 30 includes a voltage sensing unit 31, an integrated current sensing unit 32, a power calculation unit 33, a communication unit 34, and a TMU control unit 35. Generally, since voltages are the same on both of a main circuit of incoming feeder and all branch circuits, sensing each voltage is not required, and thus, only the voltage on the main circuit of the incoming feeder is sensed by a PT of the voltage sensing unit 31. Also, the CT 40 is disposed on each branch circuit to sense currents. All analog current signals received through signal lines from the CTs 40 are converted by an ADC included in the integrated current sensing unit 32 of the TMU 30.

Descriptions of the power calculation unit 33 and the communication unit 34 are the same as the power calculation unit 13 and the communication unit 14 included in the MU 10 illustrated in FIG. 3. The TMU control unit 35 controls operations of the voltage sensing unit 31, the integrated current sensing unit 32, the power calculation unit 33, and the communication unit 34 included in the TMU 30.

According to a power measuring system configured as above with reference to FIGS. 6 and 7, on each branch circuit, only the CT 40 is needed without processor devices such as a microcontroller and a DSP. Thus, installation cost for measuring power of branch circuits may be reduced. However, for incoming feeder, a high-performance ADC and arithmetic processor are needed for processing all analog current signals converged on the TMU 30. Thus, high levels of technical difficulty and cost are involved. Further, since two signal lines should be connected to the TMU 30 from a single CT 40, the number of signal lines increases as the number of branch circuits increases, which makes wiring difficult and detracts from a clean outward appearance.

### SUMMARY OF THE INVENTION

The present invention provides a power measuring system for efficiently, simply, and easily obtaining power and power quality data of incoming feeder and a branch circuit.

Embodiments of the present invention provide power measuring systems for measuring power of both of a main circuit and a branch circuit, including a voltage sensing unit configured to obtain an analog voltage signal by sensing voltage of the main circuit or branch circuit, and generate a main voltage data by converting the analog voltage signal into a digital data; a current sensing unit configured to obtain an analog current signal by sensing current of the main circuit or branch circuit, and generate a main current data or sub current data by converting the analog current signal into a digital data; a current data communication unit configured to transmit the main current data or sub current data generated by current sensing unit; a voltage data communication unit configured to receive the main current data or sub current data from the current data communication unit; an integrated power calculation unit configured to calculate a main circuit power data of the main circuit using the main voltage data generated by the voltage sensing unit and the main current data generated by the current sensing unit, and calculate a branch circuit power data using the main voltage data generated by the voltage sensing unit and the sub current data received through the voltage data communication unit; and a voltage measurement control unit configured to control at least the voltage sensing unit, voltage data communication unit, and integrated power calculation unit.

In other embodiments of the present invention, power measuring systems for measuring power of both of a main circuit and a branch circuit include a voltage sensing unit configured to obtain an analog voltage signal by sensing voltage of the main circuit or branch circuit, and generate a main voltage data by converting the analog voltage signal into a digital data; a current sensing unit configured to obtain an analog current signal by sensing current of the main circuit or branch circuit, and generate a main current data or sub current data by converting the analog current signal into a digital data; a voltage data communication unit configured to transmit the main voltage data generated by the voltage sensing unit; a current data communication unit configured to receive the main voltage data sensed by the voltage sensing unit from the voltage data communication unit; an individual power calculation unit configured to calculate a main circuit power data or branch circuit power data using the main voltage data received through the current data communication unit and the main current data or sub current data generated by the current sensing unit; and a voltage measurement control unit configured to control the voltage sensing unit and voltage data communication unit.

In still other embodiments of the present invention, power measuring systems for measuring power of both of a main circuit and a branch circuit include a voltage sensing unit configured to obtain an analog voltage signal by sensing voltage of the main circuit or branch circuit, and convert the analog voltage signal into a digital data; a current sensing unit configured to obtain an analog current signal by sensing current of the main circuit or branch circuit, and generate a main current data or sub current data by converting the analog current signal into a digital data; a voltage analog-to-digital converter (ADC) configured to receive the analog voltage signal outputted from the voltage sensing unit, and generate a main voltage data by converting the analog voltage signal into a digital data; an individual power calculation unit configured to calculate a main circuit power data or branch circuit power data using the main voltage data generated by the voltage ADC and the main current data or sub current data generated by the current sensing unit a voltage measurement control unit configured to control the voltage sensing unit; and a current measurement control unit configured to control at least the voltage ADC, current sensing unit, and individual power calculation unit.

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIG. 1 illustrates a configuration of a distribution panel or cabinet panel;

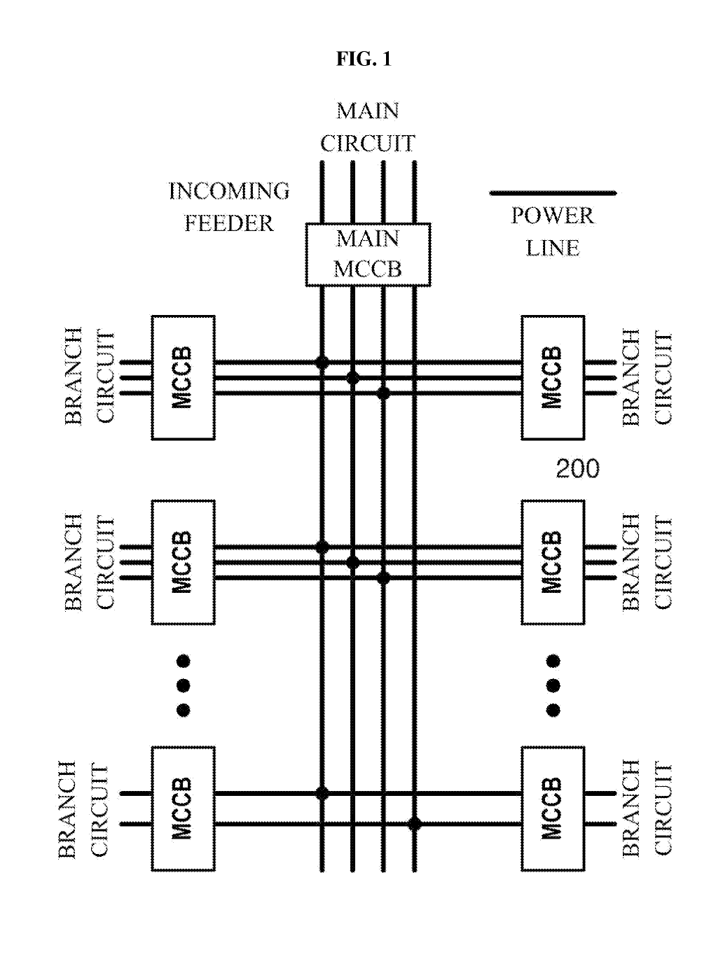

FIG. 2 illustrates an exemplary configuration of a conventional power measuring system installed on a distribution panel or cabinet panel;

FIG. 3 illustrates a configuration of a conventional measuring unit (MU);

FIG. 4 illustrates an exemplary form of a conventional MU;

FIG. 5 illustrates a configuration of a conventional display unit (DU);

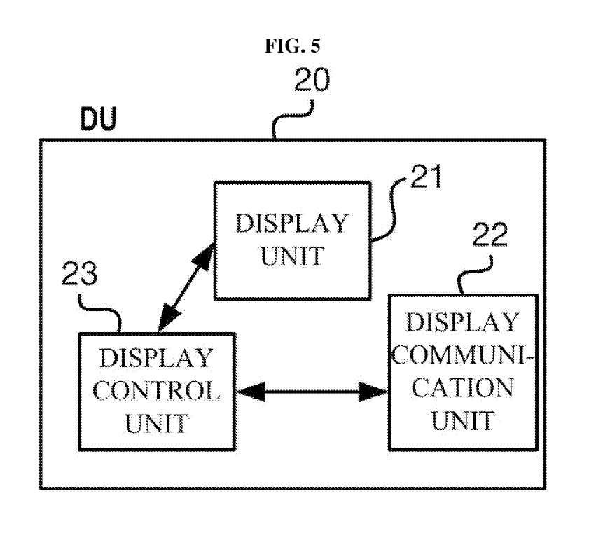

FIG. 6 illustrates another exemplary configuration of a conventional power measuring system installed on a distribution panel or cabinet panel;

FIG. 7 illustrates a configuration of a conventional total measuring unit (TMU);

FIG. 8 illustrates an overall configuration of a power measuring system installed on a distribution panel or cabinet panel according to a first embodiment of the present invention;

FIG. 9 illustrates a detailed configuration of the power measuring system according to the first embodiment of the present invention;

FIG. 10 illustrates a configuration of a power display device according to the first embodiment of the present invention;

FIG. 11 illustrates a configuration of a power supply device according to the first embodiment of the present invention;

FIG. 12 illustrates an overall configuration of a power measuring system installed on a motor control center according to a second embodiment of the present invention;

FIG. 13 illustrates a detailed configuration of the power measuring system according to the second embodiment of the present invention;

FIG. 14 illustrates a detailed configuration of a power measuring system according to a third embodiment of the present invention; and

FIG. 15 illustrates a configuration of a voltage measuring device including a power supply unit according to a fourth embodiment of the present invention.

### DETAILED DESCRIPTION OF PREFERRED EMBODIMENTS

Preferred embodiments of the present invention will be described below in more detail with reference to the accompanying drawings. The present invention may, however, be embodied in different forms and should not be constructed as limited to the embodiments set forth herein. Rather, these embodiments are provided so that this disclosure will be thorough and complete, and will fully convey the scope of the present invention to those skilled in the art.

Hereinafter, a power measuring system according to preferred embodiments of the present invention will be described in detail with reference to the accompanying drawings.

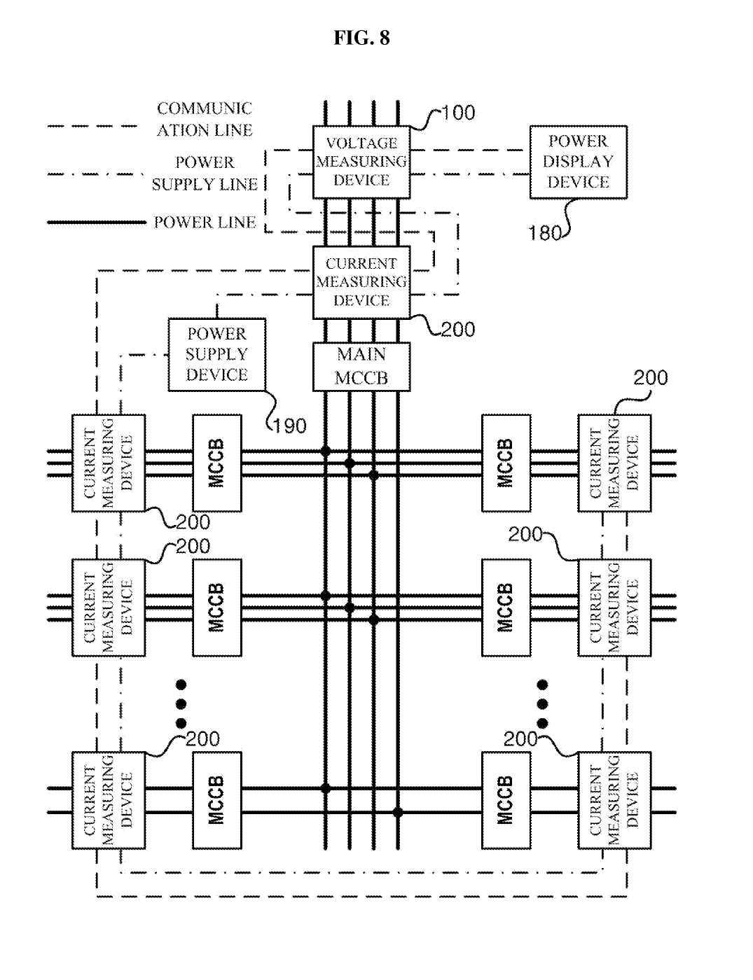

FIG. 8 illustrates an overall configuration of a power measuring system installed on a distribution panel or cabinet panel according to a first embodiment of the present invention. The power measuring system includes a voltage measuring device 100 and a current measuring device 200. The voltage measuring device 100 measures voltage on a main circuit of incoming feeder, and receives measured data of currents which flow in the main circuit to calculate power of the main circuit.

The voltage measuring device 100 also receives measured data of currents which flow in branch circuits to calculate power of the branch circuits, and transmits the power of the main circuit or branch circuits to a power display device 180. The current measuring device 200 measures currents flowing in the main circuit or branch circuits and transmits the measured currents to the voltage measuring device 100.

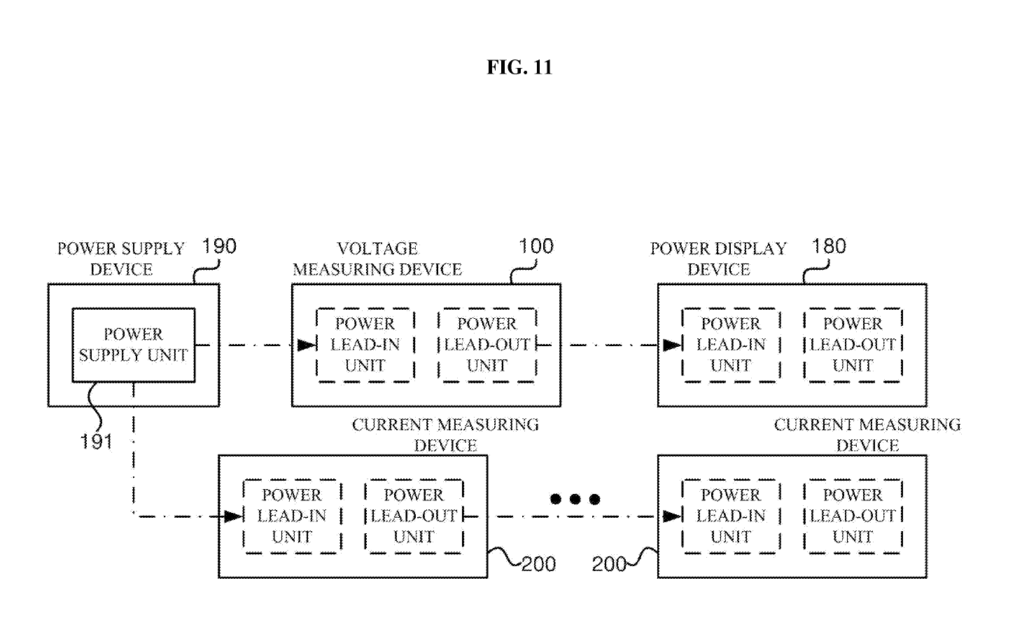

A power supply device 190 supplies power needed for operating the voltage measuring device 100, the current measuring device 200, and the power display device 180. For supplying this power, power supply lines are respectively connected to the voltage measuring device 100, the current measuring device 200, and the power display device 180. The power supply device 190 will be described in detail later with reference to FIG. 11.

Communication lines are interconnected between the voltage measuring device 100, the current measuring device 200, and the power display device 180 to transmit and receive a power measurement data, which includes voltage and current data converted into digital data from sensed voltage and current and a power data calculated using the voltage and current data. To this end, if serial communication such as RS-485, which is capable of multi-drop, is used, the communication lines interconnected between the voltage measuring device 100, the current measuring device 200, and the power display device 180 may be further simplified.

It could be understood that the power measurement data may include not only the voltage, current, and power data but also various data which are generated using the foregoing data and are capable of expressing power quality.

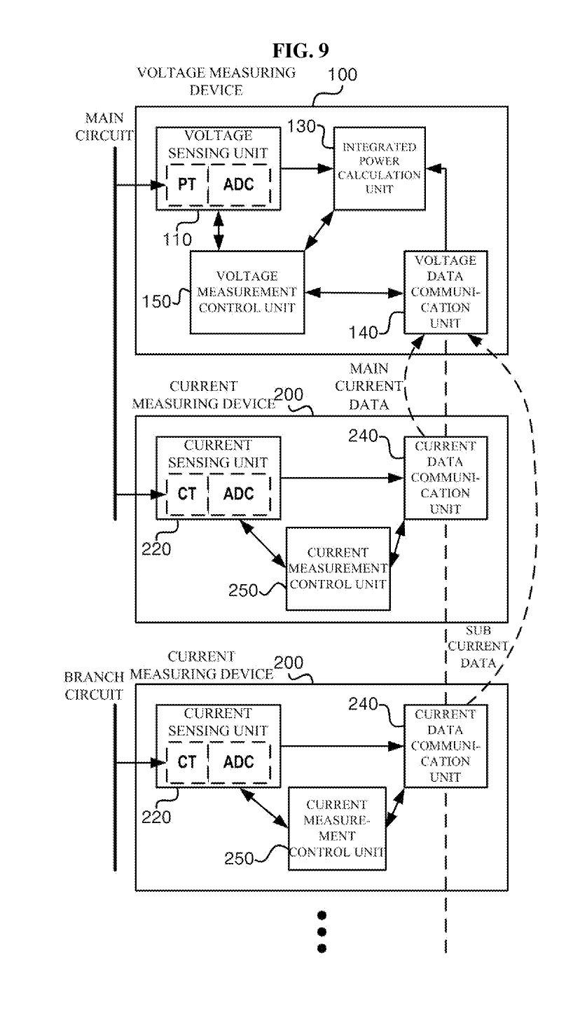

FIG. 9 illustrates a detailed configuration of the power measuring system according to the first embodiment of the present invention. The voltage measuring device 100 includes a voltage sensing unit 110, an integrated power calculation unit 130, a voltage data communication unit 140, and a voltage measurement control unit 150. The voltage sensing unit 110 converts an analog voltage signal of a main circuit, which is measured by a potential transformer (PT), using an analog-to-digital converter (ADC) to generate main voltage data.

The voltage data communication unit 140 receives main current data or sub current data corresponding to current of a main circuit or branch circuit, which is generated by the current measuring device 200. The generation of the main current data or sub current data corresponding to current of a main circuit or branch circuit will be described later.

In the present embodiment, it is described that the voltage sensing unit 110 measures voltage of a main circuit. However, the voltage sensing unit 110 may also sense voltage of a branch circuit besides the main circuit to generate the main voltage data, and for simple wiring, it is preferable that a main circuit or branch circuit closest to the voltage sensing unit 110 is sensed.

The integrated power calculation unit 130 calculates main circuit power data of a main circuit or branch circuit power data of a branch circuit, by using the main voltage data generated by the voltage sensing unit 110, and the main current data or sub current data received through the voltage data communication unit 140.

It could be understood that not only the main circuit power data or branch circuit power data but also various data, which are calculated using the main voltage data and the main current data or sub current data for expressing power quality, may be used.

The voltage measurement control unit 150 controls operations of the voltage sensing unit 110, the integrated power calculation unit 130, and the voltage data communication unit 140 using commands provided to a microcontroller and a digital signal processor (DSP), and includes a program configured to operate the voltage measuring device 100. For correctly calculating the main circuit power data and branch circuit power data, it is preferable that the voltage measurement control unit 150 synchronizes the generation timing of the main voltage data, the main current data, and the sub current data.

The current measuring device 200 includes a current sensing unit 220, a current data communication unit 240, and a current measurement control unit 250. The current sensing unit 220 converts an analog current signal of a main circuit or branch circuit, which is measured by a current transformer (CT), using an ADC to generate main current data or sub current data. The current data communication unit 240 transmits the main current data or sub current data corresponding to current of a main circuit or branch circuit, which is generated by the current sensing unit 220, to the voltage measuring device 100.

Like the voltage measurement control unit 150, the current measurement control unit 250 controls operations of the current sensing unit 220 and the current data communication unit 240 using commands provided to a microcontroller and a DSP, and includes a program configured to operate the current measuring device 200. For the integrated power calculation unit 130 to correctly calculate the main circuit power data and branch circuit power data, it is preferable that the current measurement control unit 250 synchronizes the generation timing of the main current data or sub current data with the generation timing of the main voltage data.

For transmitting the main current data or sub current data from the current data communication unit 240 to the voltage data communication unit 140, serial communication such as RS-485, which is capable of multi-drop, is used. By virtue of the serial communication capable of multi-drop, communication lines for communication between the voltage measuring device 100 and the current measuring device 200 may be more simply configured. Also, even though the number of current measuring devices 200 is increased, communication lines may be sequentially connected to be extended through the voltage measuring device 100 or another current measuring device 200. Therefore, even though the number of branch circuits is increased, communication lines may be simply configured, and thus, efficiency of the power measuring system may be improved.

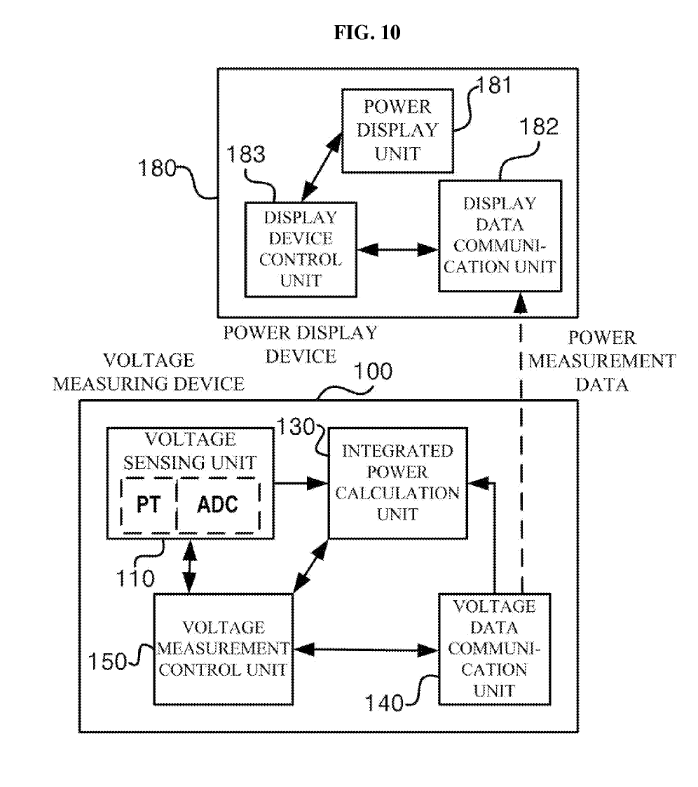

FIG. 10 illustrates a power display device according to the first embodiment of the present invention. The power display device 180 includes a power display unit 181, a display data communication unit 182, and a display control unit 183. The power display unit 181 displays power measurement data which includes the main circuit power data or branch circuit power data calculated by the voltage measuring device 100. The power display unit 181 may display the data in various forms including analog and digital forms.

The display data communication unit 182 receives the power measurement data including the main circuit power data or branch circuit power data calculated by the integrated power calculation unit 130 of the voltage measuring device 100 so that the received data is displayed on the power display unit 181. The display control unit 183 controls operations of the power display device 180 including the power display unit 181 and the display data communication unit 182.

FIG. 11 illustrates a power supply device according to the first embodiment of the present invention. The power supply device 190 serves to supply power needed for operating the power measuring system to each device, and includes a power supply unit 191. In the case that a power lead-in unit and a power lead-out unit are additionally provided to the voltage measuring device 100, the current measuring device 200, or the power display device 180 included in the power measuring system, power supply lines may be sequentially connected through the voltage measuring device 100, another current measuring device 200, or the power display device 180 so that wiring of the power supply lines is further simplified.

Also, in the case of combining the communication lines described above with reference to FIGS. 8 to 10 and the power supply lines described above with reference to FIG. 11, wiring of the power measuring system may become easier and simpler so as to improve the efficiency of the power measuring system. In the case of providing the power supply unit 191 additionally to the voltage measuring device 100, the current measuring device 200, or the power display device 180, simplicity may be increased because the power supply device 190 does not need to be provided separately.

In addition, it could be understood that the voltage measuring device 100 and the current measuring device 200 may be integrated as a single device, and in the case that the voltage measuring device 100 and the current measuring device 200 are integrated as an integrated current measuring device 200 for measuring voltage and current of a main circuit, main current data generated by the integrated current measuring device 200 does not need to be transmitted through communication lines. Also, the power supply unit 191 may be further integrated to the device which integrates the voltage measuring device 100 and the current measuring device 200, and various other similar configurations are possible.

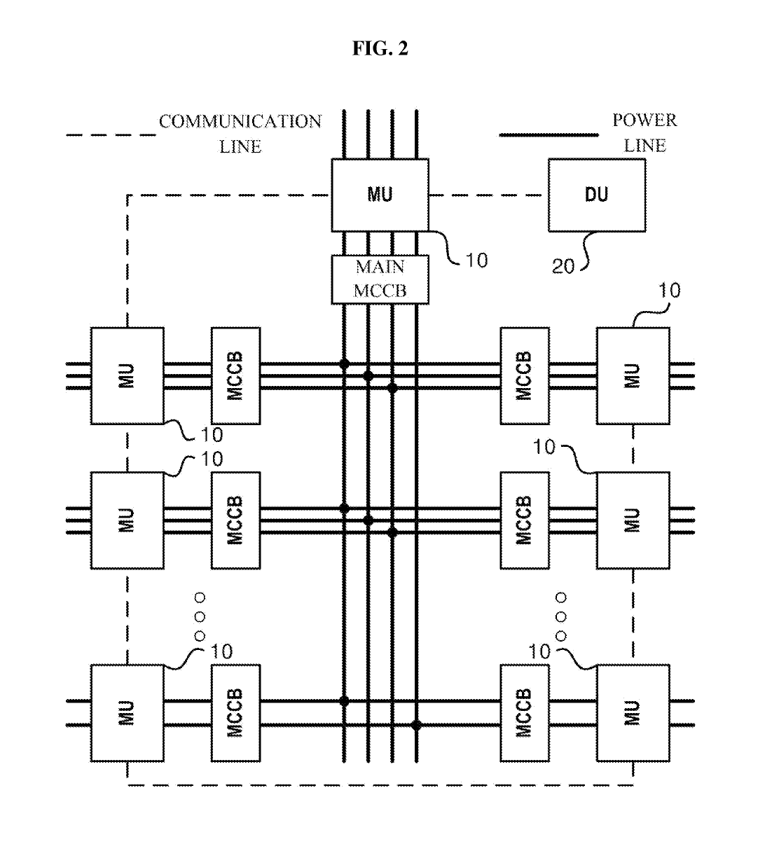

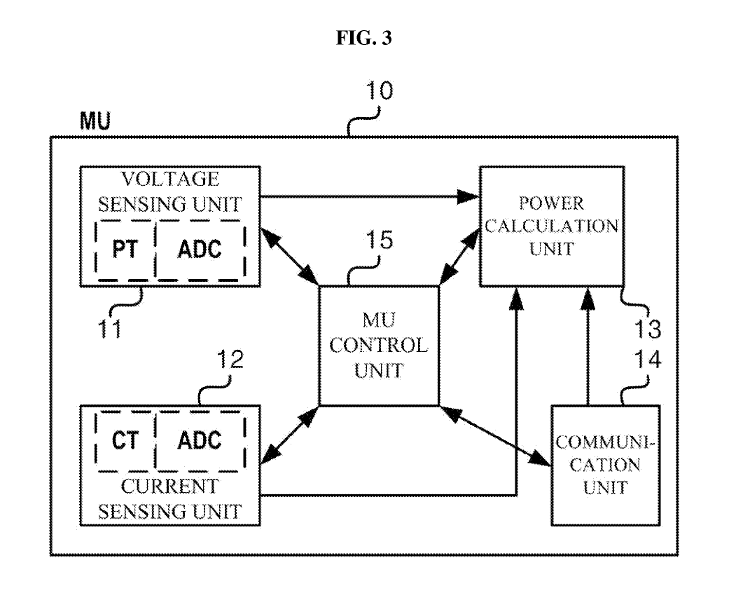

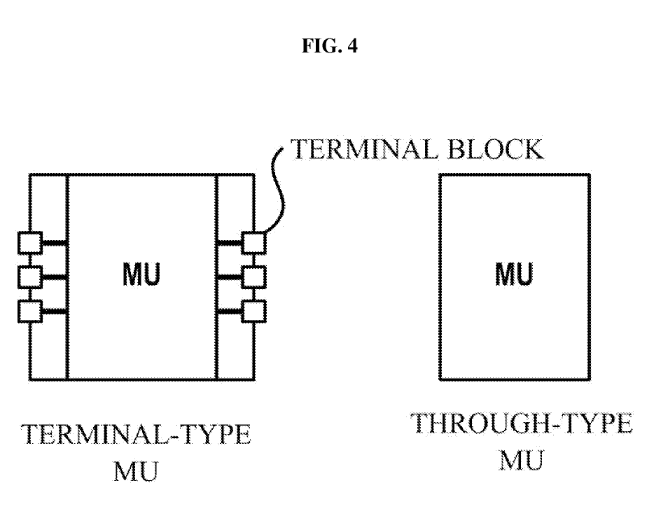

According to the conventional MU illustrated in FIGS. 2 to 4, all voltages and currents of main circuit and each branch circuit respectively are sensed and digitalized. For calculating instantaneous power of a branch circuit, voltage and current of a branch circuit should be simultaneously sensed and digitalized before the calculation. If voltage and current of different timings are used, a wrong power value would be obtained. Therefore, according to the prior art, it is considered to be reasonable that voltage and current of a branch circuit are used for calculating the power of a branch circuit. Therefore, according to the prior art, a PT and a CT are provided to each MU, and need to be connected to power lines. Particularly, even in the case of using a through-type MU, a PT needs to be directly connected to a power line.

In comparison with the prior art, according to the first embodiment of the present invention, a main voltage data obtained by sensing and digitalizing voltage of a main circuit is used for calculating the power of a branch circuit. For calculating the power of a branch circuit, voltage data of a branch circuit is not used, but voltage data of a main circuit is used. Therefore, according to the first embodiment of the present invention, voltage data of each branch circuit does not need to be generated. That is, a PT for generating voltage data of a branch circuit is not needed, and a PT does not need to be connected to a branch circuit. It is very complicated to dispose a PT on each branch circuit and connect them through wires; however, this is not needed in the first embodiment of the present invention. According to the first embodiment of the present invention, since a CT senses a current signal without contacting a power line, a connection with a branch circuit is not needed for the current measuring device 200 disposed on each branch circuit.

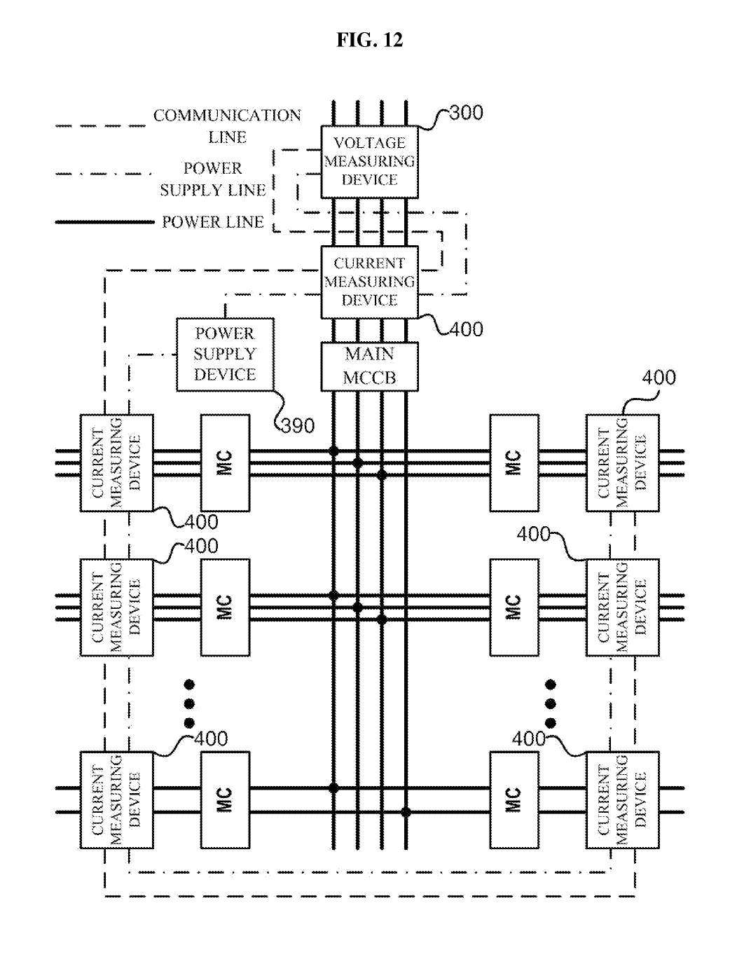

FIG. 12 illustrates an overall configuration of a power measuring system installed on a motor control center according to a second embodiment of the present invention. Generally, a motor control center (MCC) is configured to dispose a motor controller (MC) and an electronic over current relay (EOCR) on each branch circuit to thereby prevent over current from flowing to a motor connected to each branch circuit.

According to the second embodiment of the present invention, a current measuring device is configured using a current measuring function of the EOCR. Also, a power display unit 381, which displays power measurement data including main circuit power data and branch circuit power data described above referring to FIG. 10, is further included in a voltage measuring device 300.

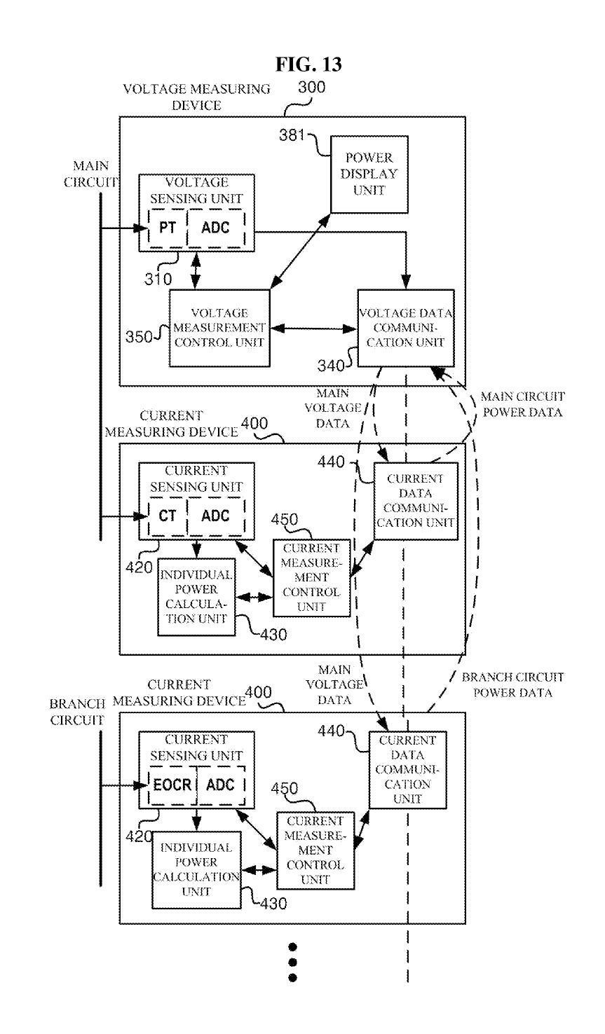

FIG. 13 illustrates a detailed configuration of the power measuring system according to the second embodiment of the present invention. The voltage measuring device 300 includes a voltage sensing unit 310, a voltage data communication unit 340, a voltage measurement control unit 350, and a power display unit 381. The voltage sensing unit 310 and the power display unit 381 are the same as those illustrated in FIGS. 9 and 10, respectively.

The voltage data communication unit 340 transmits main voltage data generated by the voltage sensing unit 310 to the current measuring device 400, and receives main circuit power data of main circuit or branch circuit power data of branch circuit calculated by the current measuring device 400 using the main voltage data. The calculation of the main circuit power data or branch circuit power data will be described later.

The voltage measurement control unit 350 controls operations of the voltage sensing unit 310 and the voltage data communication unit 340 using commands provided to a microcontroller and a DSP, and includes a program configured to operate the voltage measuring device 300. For correctly generating the main circuit power data and branch circuit power data, it is preferable that the voltage measurement control unit 350 synchronizes the generation timing of the main voltage data with the generation timing of the main current data or sub current data which correspond to the current of a main circuit or branch circuit.

The current measuring device 400 includes a current sensing unit 420, an individual power calculation unit 430, a current data communication unit 440, and a current measurement control unit 450. The current sensing unit 420, which senses a main circuit, converts an analog current signal of a main circuit measured by a CT using an ADC to thereby generate main current data. The current sensing unit 420, which senses a branch circuit, converts an analog current signal of a branch circuit measured by an EOCR using an ADC to thereby generate sub current data.

The current data communication unit 440 receives the main voltage data corresponding to voltage of a main circuit, which is generated by the voltage measuring device 300. When voltages applied to a main circuit and a branch circuit are the same, the voltage of the branch circuit does not need to be sensed, and the individual power calculation unit 430 calculates main circuit power data of a main circuit or branch circuit power data of a branch circuit using the main voltage data received from the current data communication unit 440, and the main current data or sub current data generated by a respective current sensing unit 420 which senses a main circuit or branch circuit.

It could be understood that not only the main circuit power data or branch circuit power data but also various other data related with power quality, which are calculated using the main voltage data and the main current data or sub current data, may be used. The current data communication unit 440 transmits the various data about power quality including the main circuit power data and the branch circuit power data to the voltage measuring device 300.

Like the voltage measurement control unit 350, the current measurement control unit 450 controls operations of the current sensing unit 420, the individual power calculation unit 430, and the current data communication unit 440 using commands provided to a microcontroller and a DSP, and includes a program configured to operate the current measuring device 400. For correctly calculating the main circuit power data and branch circuit power data, it is preferable that the current measurement control unit 450 synchronizes the generation timing of the main voltage data received from the current data communication unit 440 with the generation timing of the main current data or sub current data.

For transmitting the main voltage data, main circuit power data, or branch circuit power data between the voltage data communication unit 340 and the current data communication unit 440, serial communication such as RS-485, which is capable of multi-drop, is used. The serial communication capable of multi-drop operates as described above with reference to FIG. 9.

According to the conventional MU illustrated in FIGS. 2 to 4, all voltages and currents of main circuit and each branch circuit respectively are sensed and digitalized. For calculating instantaneous power of a branch circuit, voltage and current of a branch circuit should be simultaneously sensed and digitalized before the calculation. If voltage and current of different timings are used, a wrong power value would be obtained. Therefore, according to the prior art, it is considered to be reasonable that voltage and current of a branch circuit are used for calculating the power of a branch circuit. Therefore, according to the prior art, a PT and a CT are provided to each MU, and need to be connected to power lines. Particularly, even in the case of using a through-type MU, a PT needs to be directly connected to a power supply line.

In comparison with the prior art, according to the second embodiment of the present invention, main voltage data obtained by sensing and digitalizing voltage of a main circuit is used for calculating power of a branch circuit. For calculating power of a branch circuit, voltage data of a branch circuit is not used, but voltage data of a main circuit is used. Therefore, according to the second embodiment of the present invention, voltage data of each branch circuit does not need to be generated. That is, a PT for generating voltage data of a branch circuit is not needed, and a PT does not need to be connected to a branch circuit. It is very complicated to dispose a PT on each branch circuit and connect them through wires; however, this is not needed in the second embodiment of the present invention. According to the second embodiment of the present invention, since a CT senses a current signal without contacting a power line, a connection with a branch circuit is not needed for the current measuring device 400 disposed on each branch circuit.

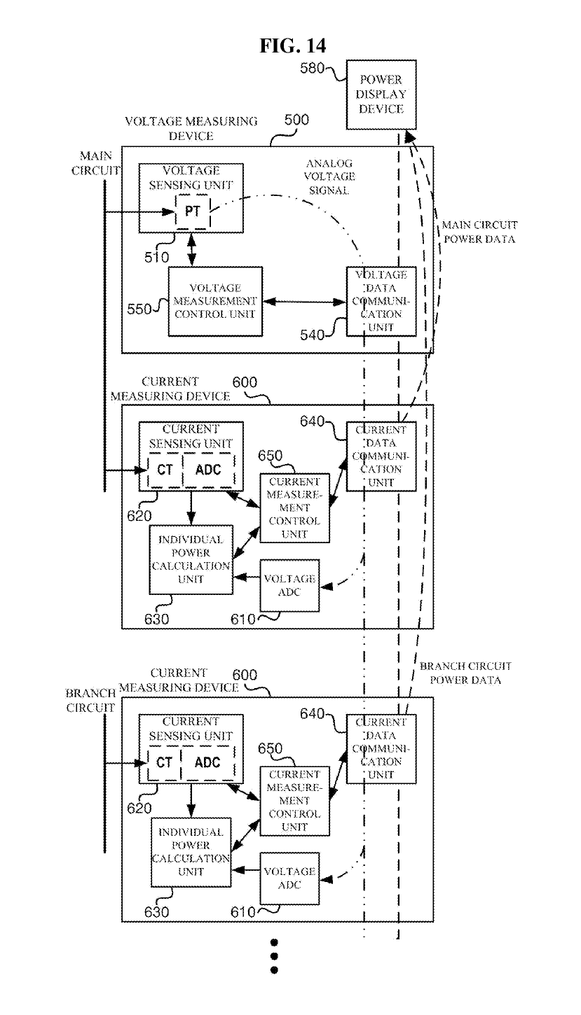

FIG. 14 illustrates a detailed configuration of a power measuring system according to a third embodiment of the present invention. According to the third embodiment of the present invention, an analog voltage signal sensed by a voltage sensing unit 510 of a voltage measuring device 500 is transmitted to a current measuring device 600 so that power may be calculated without data synchronization in the current measuring device 600.

The voltage measuring device 500 includes the voltage sensing unit 510, a voltage data communication unit 540, and a voltage measurement control unit 550. The voltage sensing unit 510 including a PT generates an analog voltage signal corresponding to voltage of a main circuit, and transfers the analog voltage signal to the current measuring device 600.

The voltage data communication unit 540 of the voltage measuring device 500 transmits power measurement data, which includes voltage and current data converted into digital data from sensed voltage and current and power data calculated using the voltage and current data, to a power display device 580 to display the power measurement data. It could be understood that the power display unit 381 of FIG. 13 instead of the power display device 580 may be further provided to the voltage measuring device 500.

In addition, in the case that a communication line is connected from the current measuring device 600 to the power display device 580 without passing through the voltage measuring device 500, the power measurement data, which includes voltage and current data converted into digital data from sensed voltage and current and power data calculated using the voltage and current data, may be directly transmitted to the power display device 580 to be displayed.

An analog voltage signal sensed by the PT of the voltage sensing unit 510 included in the voltage measuring device 500 is transferred to the current measuring device 600 through a signal line. It should be noted that not digital data but an analog voltage signal is transferred to each current measuring device 600. The voltage data communication unit 540 may also receive main circuit power data or branch circuit power data calculated by the current measuring device 600 to display the received data on the power display device 580. The calculation of the main circuit power data or branch circuit power data will be described later. The voltage measurement control unit 550 operates as described above with reference to FIG. 13.

The current measuring device 600 includes a current sensing unit 620, an individual power calculation unit 630, a current data communication unit 640, and a current measurement control unit 650. Even though the voltages applied to a main circuit and a branch circuit are the same, there is inconvenience in synchronizing generation timing of main voltage data and sub current data to correctly calculate branch circuit power data using main voltage data which corresponds to voltage of a main circuit.

According to the third embodiment of the present invention, a voltage ADC 610 is included in the current measuring device 600 so that an analog voltage signal sensed in the voltage measuring device 500 is transferred to the current measuring device 600, and main circuit power data or branch circuit power data is calculated using the analog voltage signal. Thus, a processing load due to the synchronization may be lightened, thereby improving efficiency of the power measuring system.

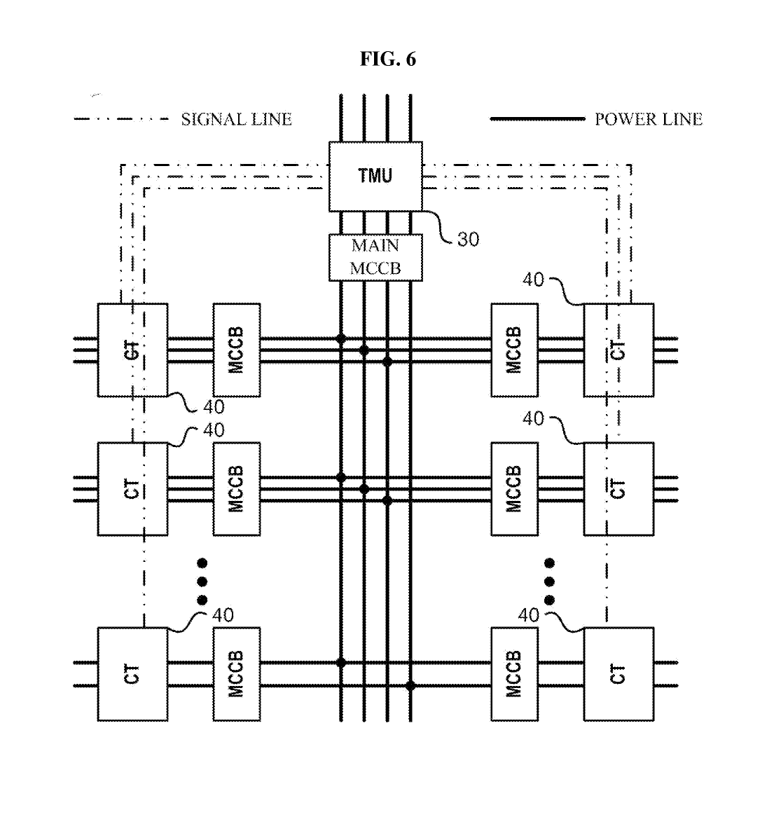

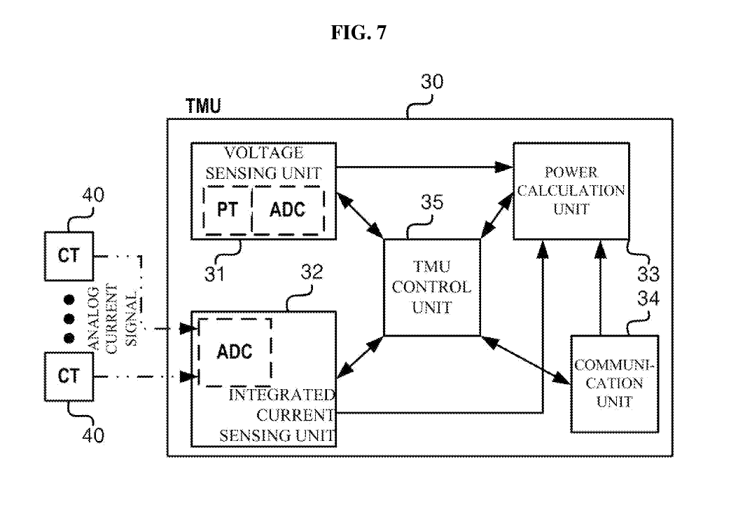

According to the third embodiment of the present invention, the current measuring device 600 may be provided with a terminal for receiving an analog voltage signal from the voltage measuring device 500. While an analog current signal is used according to the configuration described above with reference to FIGS. 6 and 7, where the conventional TMU and CT are adopted, an analog voltage signal is used according to the third embodiment of the present invention. Therefore, even though the number of current measuring devices 600 is increased, multiple current measuring devices 600 may share a single signal line, and thus, signal lines may be simply configured.

As in the serial communication capable of multi-drop which is used for data transmission between the voltage data communication unit 540 and the current data communication unit 640, the signal line for transmitting an analog voltage signal is sequentially connected to another signal line through another current measuring device 600 so that an analog voltage signal sensed in the voltage measuring device 500 is shared by a plurality of current measuring devices 600 to be used for calculating main circuit power data or branch circuit power data.

In addition, it could be understood that the signal line for transmitting an analog voltage signal may be integrated with the communication line for transmitting main circuit power data or branch circuit power data so that wiring for the above-described configuration may be simpler. For instance, an analog voltage signal sensed by a PT of the voltage sensing unit 510 included in the voltage measuring device 500 may be connected to a spare connection terminal of the voltage data communication unit 540, and the analog voltage signal may be transmitted through a spare wire of a communication line so that the current measuring device 600 may use the analog voltage signal sensed in the voltage measuring device 500 through a spare connection terminal, which is connected to the wire for transmitting the analog voltage signal, of the current data communication unit 640 of the current measuring device 600.

The voltage ADC 610 converts an analog voltage signal of a main circuit received from the voltage measuring device 500 into a digital form to generate main voltage data for calculating main circuit power data or branch circuit power data in the current measuring device 600 by using the analog voltage signal of a main circuit. This method may be used when voltages of a main circuit and a branch circuit are the same.

Also, when the voltage ADC 610 generates the main voltage data by converting the analog voltage signal received from the voltage measuring device 500 into a digital form, it is preferable that the voltage ADC 610 appropriately adjusts a signal level of the main voltage data to a range for easily calculating main circuit power data or branch circuit power data. The current sensing unit 620 operates as described above with reference to FIG. 9.

The individual power calculation unit 630 respectively calculates main circuit power data or branch circuit power data using the main voltage data generated by the voltage ADC 610, and the main current data generated by the current sensing unit 620 which senses a main circuit, or the sub current data generated by the current sensing unit 620 which senses a branch circuit.

The current data communication unit 640 transmits the calculated main circuit power data or branch circuit power data to the power display device 580. Also, the main circuit power data or branch circuit power data may be transmitted to the voltage measuring device 500 to display the power data on the power display device 580. In the case that the voltage measuring device 500 includes a power display unit such as the power display unit 381 of FIG. 13, the main circuit power data or branch circuit power data may be transmitted to the voltage measuring device 500 to display the power data on the power display unit.

As described above, the current measuring device 600 does not need a PT which senses voltage, and accordingly a PT does not need to be connected with a power line. Thus, simplicity of the power measuring system may be increased. Also, since an analog voltage signal is transferred for measuring power, a signal line may be shared, and thus simplicity of a signal line may be increased.

Like the voltage measurement control unit 550, the current measurement control unit 650 controls operations of the voltage ADC 610, the current sensing unit 620, the individual power calculation unit 630, and the current data communication unit 640 using commands provided to a microcontroller and a DSP, and includes a program configured to operate the current measuring device 600. The current measuring device 600 configured as described above does not need to perform the synchronization, and thus, efficiency of the power measuring system is improved.

For transmitting the power measurement data including the main circuit power data or branch circuit power data from the current data communication unit 640 or voltage data communication unit 540 to display the power measurement data, serial communication such as RS-485, which is capable of multi-drop, is used. The serial communication capable of multi-drop operates as described above with reference to FIG. 9. In addition, a connection line for receiving an analog voltage signal of a main circuit may also be configured by using a spare communication line which is not used for the serial communication capable of multi-drop, and thus, wiring of the power measuring system may be made simpler.

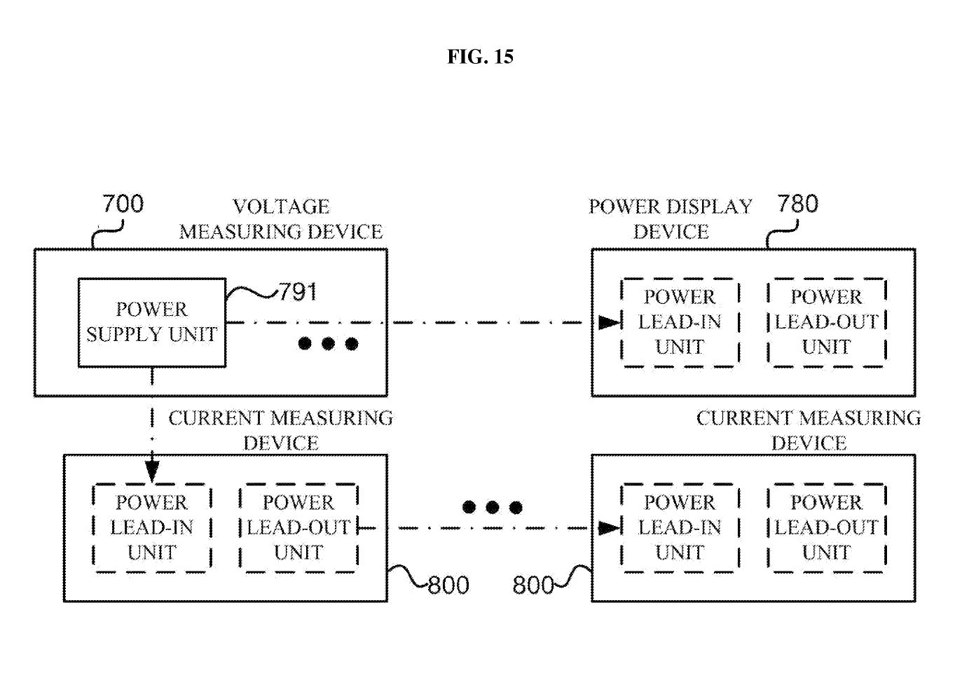

FIG. 15 illustrates a voltage measuring device including a power supply unit according to a fourth embodiment of the present invention. According to the fourth embodiment of the present invention, a voltage measuring device 700 includes a power supply unit 791 which is the same as the power supply unit described above with reference to FIG. 11. Although elements such as the voltage sensing unit, the current sensing unit, the voltage data communication unit, and the voltage measurement control unit described above with reference to FIGS. 9, 13 and 14 are not illustrated in FIG. 15, it could be understood that devices of FIG. 15 respectively include these elements.

Although the power supply unit 791 is included in the voltage measuring device 700 according to the fourth embodiment of the present invention, the power supply unit 791 may also be included in a current measuring device 800 or a power display device 780. As described above with reference to FIG. 11, in the case that a power lead-in unit and a power lead-out unit are additionally provided, power supply lines may be sequentially connected to each other through the voltage measuring device 700, another current measuring device 800, or the power display device 780 so that wiring of the power supply lines may be more simplified.

Also, as described above with reference to FIG. 11, in the case of integrating the communication lines described above with reference to FIGS. 8 to 10 with the power supply lines described above with reference to FIG. 15, wiring of the power measuring system may be easier and simpler so that efficiency of the power measuring system is improved.

Although it has been described respectively with reference to FIGS. 13 and 15 that the voltage measuring device 300 includes the power display unit 381, and the voltage measuring device 700 includes the power supply unit 791, it could be understood that a voltage measuring device may also be configured to include both of the power display unit 381 of FIG. 13 and the power supply unit 791 of FIG. 15.

Also, it is preferable that the power display units 181 and 381 of the first and second embodiments are installed on the outside of a door of a panel which includes a distribution panel, cabinet panel, or motor control center, or the door of the panel is configured to be transparent for the distribution panel, cabinet panel, or motor control center to be seen from the outside.

According to an aspect of the present invention, a power measuring system can efficiently, simply, and easily obtain power and power quality data of incoming feeder and a branch circuit of a distribution panel, cabinet panel, or motor control center.

Also, according to an aspect of the present invention, since main voltage data digitalized from a sensed voltage of a main circuit is commonly used, simplicity and efficiency of a power measuring system can be increased.

Also, according to an aspect of the present invention, since voltage data, which is obtained by digitalizing a sensed voltage of one power line in a distribution panel, cabinet panel, or motor control center, is used for calculating power of another power line, simplicity and efficiency of a power measuring system can be increased.

Also, according to an aspect of the present invention, since an analog voltage signal, which is sensed from one power line in a distribution panel, cabinet panel, or motor control center, is shared, a signal line for transferring an analog signal can be simplified, and the burden of synchronization, which is required for calculating power using transferred digitalized voltage data, can be reduced.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

1. A power measuring system for measuring power of both a main circuit and a branch circuit, comprising:
a voltage sensing unit configured to obtain an analog voltage signal by sensing voltage of the main circuit, and generate main voltage data by converting the analog voltage signal to digital data;
a first current sensing unit configured to obtain a main analog current signal by sensing current of the main circuit, and generate a main current data by converting the main analog current signal to digital data;
a second current sensing unit configured to obtain a branch analog current signal by sensing current of the branch circuit, and generate sub current data by converting the branch analog current signal to digital data;
a current data communication unit configured to transmit the sub current data generated by the second current sensing unit; and
an integrated power calculation unit configured to calculate main circuit power data of the main circuit by using the main voltage data generated by the voltage sensing unit and the main current data generated by the first current sensing unit, and calculate branch circuit power data of the branch circuit by using the main voltage data generated by the voltage sensing unit and the sub current data received through the current data communication unit.

2. A power measuring system for measuring power of both a main circuit and a branch circuit, comprising:
a voltage sensing unit configured to obtain an analog voltage signal by sensing voltage of the main circuit, and generate main voltage data by converting the analog voltage signal to digital data;
a voltage data communication unit configured to transmit the main voltage data generated by the voltage sensing unit;
a first current sensing unit configured to obtain a main analog current signal by sensing current of the main circuit, and generate main current data by converting the main analog current signal to digital data;
a second current sensing unit configured to obtain a branch analog current signal by sensing current of the branch circuit, and generate sub current data by converting the branch analog current signal to digital data;
a first individual power calculation unit configured to calculate main circuit power data of the main circuit by using the main voltage data received through the voltage data communication unit and the main current data generated by the first current sensing unit; and
a second individual power calculation unit configured to calculate branch circuit power data of the branch circuit by using the main voltage data received through the voltage data communication unit and the sub current data generated by the second current sensing unit.

3. The power measuring system of claim 1, wherein generation timing of the main voltage data, the main current data, and the sub current data are synchronized.

4. The power measuring system of claim 1, wherein serial communication capable of multi-drop is used for the current data communication unit.

5. The power measuring system of claim 2, wherein the voltage data communication unit uses serial communication capable of multi-drop.

6. A power measuring system for measuring power of both a main circuit and a branch circuit, comprising:
a voltage sensing unit configured to output an analog voltage signal by sensing voltage of the main circuit;
a first current sensing unit configured to obtain a main analog current signal by sensing current of the main circuit, and generate main current data by converting the main analog current signal to digital data;
a first voltage analog-to-digital converter (ADC) configured to receive the analog voltage signal outputted from the voltage sensing unit, and generate first main voltage data by converting the analog voltage signal to digital data;
a first individual power calculation unit configured to calculate main circuit power data of the main circuit by using the main current data generated by the first current sensing unit and the first main voltage data generated by the first voltage ADC;
a second current sensing unit configured to obtain a branch analog current signal by sensing current of the branch circuit, and generate sub current data by converting the branch analog current signal to digital data;
a second voltage ADC configured to receive the analog voltage signal outputted from the voltage sensing unit, and generate second main voltage data by converting the analog voltage signal to digital data; and
a second individual power calculation unit configured to calculate a branch circuit power data of the branch circuit by using the sub current data generated by the second current sensing unit and the second main voltage data generated by the second voltage ADC.

7. The power measuring system of claim 6, wherein the sensing of the voltage of the main circuit is performed by a potential transformer (PT) of the voltage sensing unit, the sensing of the current of the main circuit is performed by a current transformer (CT) of the first current sensing unit, and the sensing of the current of the branch circuit is performed by a CT of the second current sensing unit.

8. The power measuring system of claim 6, wherein a same signal line is used for transferring the analog voltage signal outputted by the voltage sensing unit to the first and second voltage ADCs.

9. The power measuring system of claim 1, wherein the power measuring system is installed on a distribution panel, cabinet panel, or motor control center.

10. The power measuring system of claim 1, further comprising a power display unit configured to receive and display power measurement data including the main circuit power data and the branch circuit power data.

11. The power measuring system of claim 10, wherein the power display unit is configured to be seen from the outside of a panel that includes a distribution panel, cabinet panel, or motor control center therein.

12. The power measuring system of claim 1, further comprising a power supply unit configured to supply power for operating at least the voltage sensing unit, the first current sensing unit, and the second current sensing unit.

13. The power measuring system of claim 2, wherein generation timing of the main voltage data, the main current data, and the sub current data are synchronized.

14. The power measuring system of claim 2, wherein the power measuring system is installed on a distribution panel, cabinet panel, or motor control center.

15. The power measuring system of claim 6, wherein the power measuring system is installed on a distribution panel, cabinet panel, or motor control center.

16. The power measuring system of claim 2, further comprising a power display unit configured to receive and display power measurement data including the main circuit power data and the branch circuit power data.

17. The power measuring system of claim 6, further comprising a power display unit configured to receive and display power measurement data including the main circuit power data and the branch circuit power data.

18. The power measuring system of claim 16, wherein the power display unit is configured to be seen from the outside of a panel that includes a distribution panel, cabinet panel, or motor control center therein.

19. The power measuring system of claim 2, further comprising a power supply unit configured to supply power for operating at least the voltage sensing unit, the first current sensing unit, and the second current sensing unit.

20. The power measuring system of claim 6, further comprising a power supply unit configured to supply power for operating at least the voltage sensing unit, the first current sensing unit, and the second current sensing unit.
